(19) United States
(12) Patent Application Publication
(10) Pub. No.: US 2015/0070830 A1
(43) Pub. Date: Mar. 12, 2015

(54) ELECTRONIC EQUIPMENT HOUSING DEVICE

(71) Applicant: FUJITSU LIMITED, Kawasaki-shi (JP)

(72) Inventor: FUMINOBU IWASAKI, Kawasaki (JP)

(73) Assignee: FUJITSU LIMITED, Kawasaki-shi (JP)

(21) Appl. No.: 14/339,721

(22) Filed: Jul. 24, 2014

(30) Foreign Application Priority Data
Sep. 6, 2013 (JP) 2013-185226

(51) Int. Cl. H05K 7/14; H05K 7/20

(52) U.S. Cl. CPC H05K 7/1488; H05K 7/20736
USPC 361/679.33

(57) ABSTRACT

An electronic equipment housing device includes: a first housing part in which first electronic equipment is housed; a second housing part in which second electronic equipment is housed; and a connecting and disconnecting mechanism that switches a spaced state in which the second housing part is spaced apart from the first housing part and a close state in which the second housing part is made close to the first housing part.

### CROSS-REFERENCE TO RELATED APPLICATION

This application is based upon and claims the benefit of priority of the prior Japanese Patent Application No. 2013-185226, filed on Sep. 6, 2013, the entire contents of which are incorporated herein by reference.

### FIELD

The embodiment discussed herein is related to an electronic equipment housing device.

### BACKGROUND

FIG. 12 is a trihedral figure illustrating a state of a disc enclosure in a conventional rack mount device and FIG. 13 illustrates a method of cooling the disc enclosure. FIGS. 12 and 13 illustrate a top face (at center in the drawings), a front face (at right in the drawings), and a rear face (at left in the drawings) of the disc enclosure 8.

The rack mount device not depicted, such as a storage server, includes a rack 91. A device such as the disc enclosure 8 (which will be simply referred to as enclosure 8, hereinbelow) is mounted in the rack 91.

A plurality of (24 at maximum, for instance) hard disk drives (HDDs) 801 are arranged and mounted on front side (right side in FIG. 12) in a cabinet 800 of the enclosure 8. One or more (two in an example illustrated in FIG. 12) fans 802 are mounted on rear side (left side in FIG. 12) in the cabinet 800 of the enclosure 8.

The fans 802 produce air flow in the cabinet 800 and thereby cool the HDDs 801. In the conventional enclosure, as illustrated in FIG. 13, the HDDs 801 and the like are cooled by production of the air flow from the front side toward the rear side in the cabinet 800.

Japanese Laid-open Patent Publication Nos. 2005-182610, 8-203264, 2008-251067, and 2001-148589 are examples of related art.

Depth of the rack 91 in the rack mount device is on the order of 900 to 1,000 mm in general. By contrast, depth of the enclosure 8 mounted in the rack 91 is on the order of 650 mm. Accordingly, there is a problem in that an extra space (dead space, see shaded parts in FIGS. 12 and 13) with a depth of about 300 mm is formed in rear of the enclosure 8 in the rack 91 and deteriorates space efficiency.

Therefore, it is conceivable to extend the housing 800 of the enclosure 8 in front-rear direction and to arrange the HDDs 801 in two rows in front and rear by arranging a plurality of HDDs 801 in another row in rear of the HDDs 801 arranged in a row along the front face of the enclosure 8, as illustrated in FIG. 14.

FIG. 14 is a plan view illustrating another mode of the disc enclosure in the conventional rack mount device.

In the disks 801 arranged in front and rear in FIG. 14, the plurality of disks 801 arranged in the row along the front face are referred to as front disk row 801a and the plurality of disks 801 arranged in the row in rear of and in parallel with the front disk row 801a are referred to as rear disk row 801b.

The enclosure 8 illustrated in FIG. 14 has a problem in that it is difficult to carry out maintenance work on the rear disk row 801b.

In the enclosure 8 illustrated in FIG. 14, the air flow produced by the fans 802 placed on the rear side in the cabinet 800 cools the front disk row 801a and thereafter reaches the rear disk row 801b.

Accordingly, the air flow increased in temperature by cooling the front disk row 801a flows into the rear disk row 801b. Thus another problem is caused in that decrease in cooling efficiency for the HDDs 801 of the rear disk row 801b results in decrease in product life.

### SUMMARY

According to an aspect of the invention, an electronic equipment housing device includes: a first housing part in which first electronic equipment is housed; a second housing part in which second electronic equipment is housed; and a connecting and disconnecting mechanism that switches a spaced state in which the second housing part is spaced apart from the first housing part and a close state in which the second housing part is made close to the first housing part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view illustrating an expanded state of a storage device as an example of an embodiment;

FIG. 2 is a perspective view illustrating a housed state of the storage device as the example of the embodiment;

FIGS. 3A and 3B are side views illustrating operations of a connecting and disconnecting mechanism in the storage device as the example of the embodiment;

FIG. 4 is a perspective view illustrating an appearance of the housed state of the storage device as the example of the embodiment;

FIG. 5 is a perspective view illustrating an appearance of the expanded state of the storage device as the example of the embodiment;

FIGS. 6A, 6B, and 6C illustrate paths of air flow that cools a rear disk row in the housed state of the storage device as the example of the embodiment;

FIG. 7 is an outside drawing illustrating an example of a duct in the storage device as the example of the embodiment;

FIG. 8 is a perspective view illustrating an appearance of rear side of an HDD shelf in the storage device as the example of the embodiment;

FIG. 9 is a perspective view illustrating paths of air flow in the expanded state of the storage device as the example of the embodiment;

FIGS. 10A, 10B, and 10C illustrate paths of air flow that cools a front disk row in the housed state of the storage device as the example of the embodiment;

FIG. 11 is a perspective view illustrating a housed state of the storage device as a modification of the embodiment;

FIG. 12 is a trihedral figure illustrating a state of a disc enclosure in a conventional rack mount device;

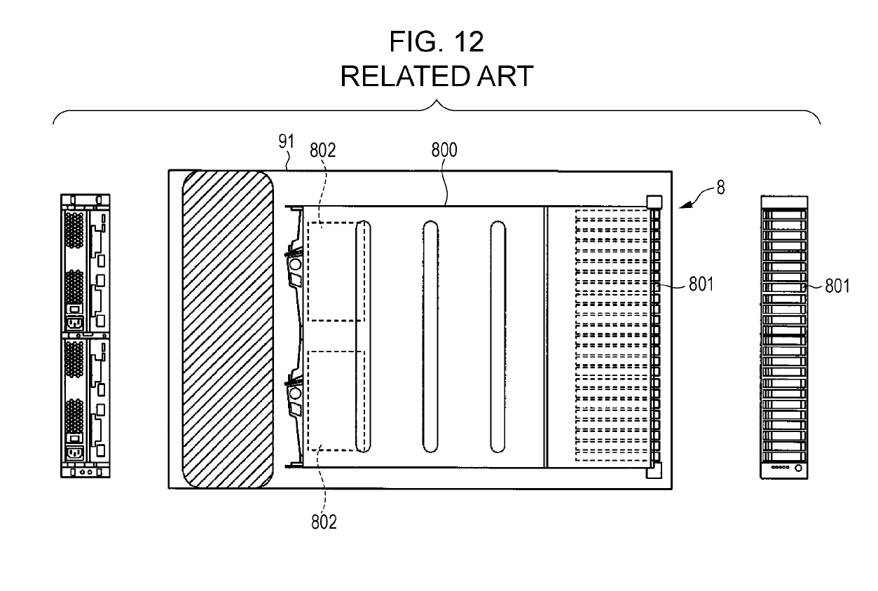

FIG. 13 illustrates a method of cooling the disc enclosure in the conventional rack mount device; and

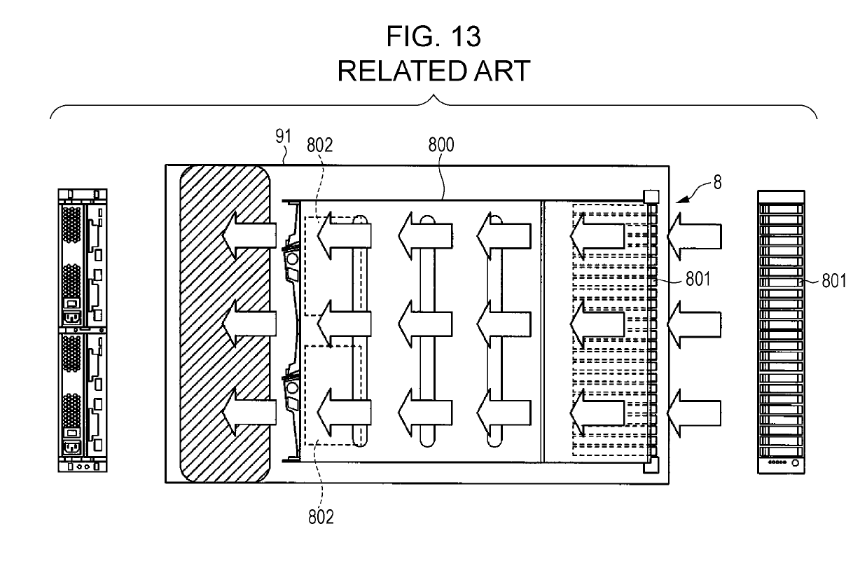

FIG. 14 is a plan view illustrating another mode of the disc enclosure in the conventional rack mount device.

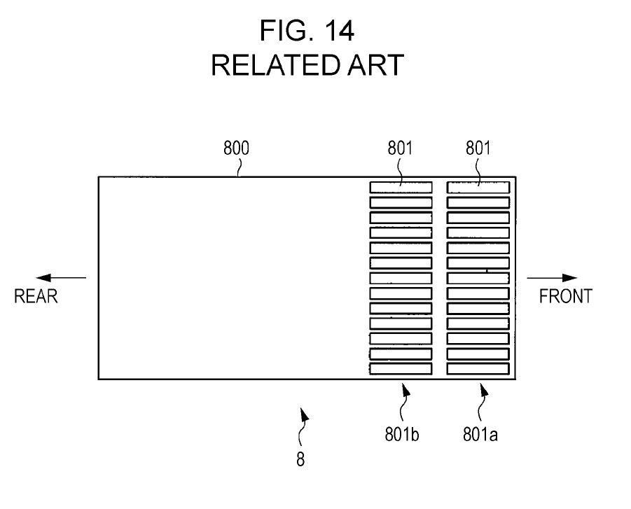

### DESCRIPTION OF EMBODIMENT

Hereinbelow, an embodiment of an electronic equipment housing device will be described with reference to the accompanying drawings. The embodiment described below, however, is merely exemplary and is not intended to exclude application of various modifications and techniques that are not specified for the embodiment. That is, the embodiment may be implemented with various modifications without departing from purport of the embodiment. The drawings do not imply provision of only components illustrated in the drawings but allow inclusion of other functions and the like.

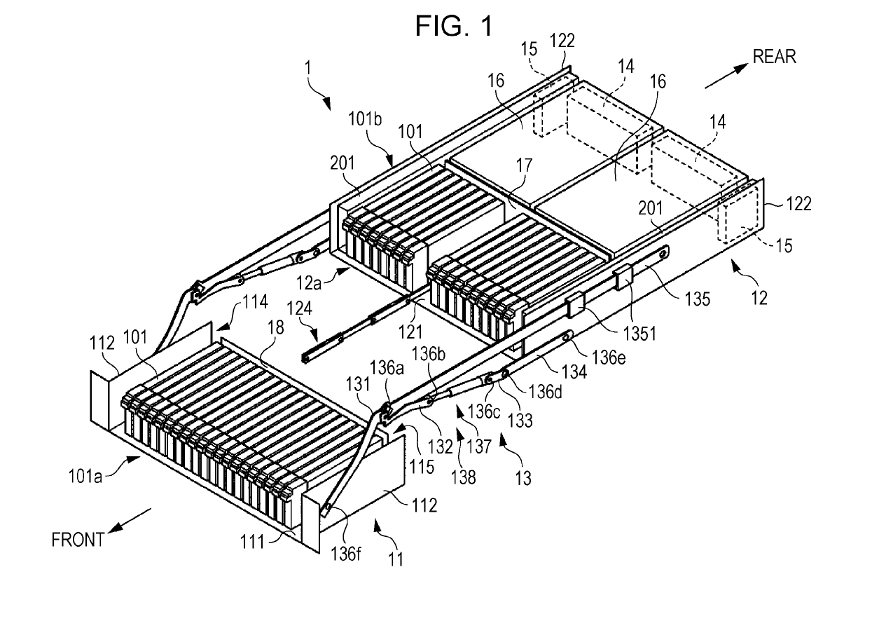

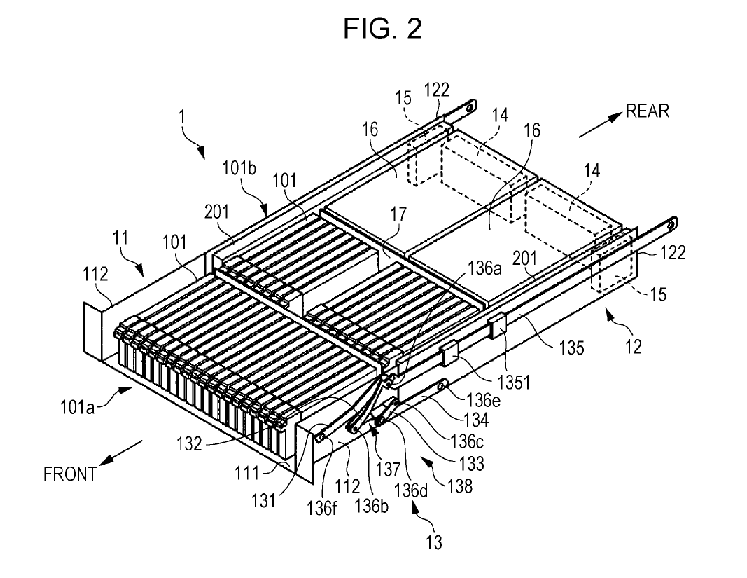

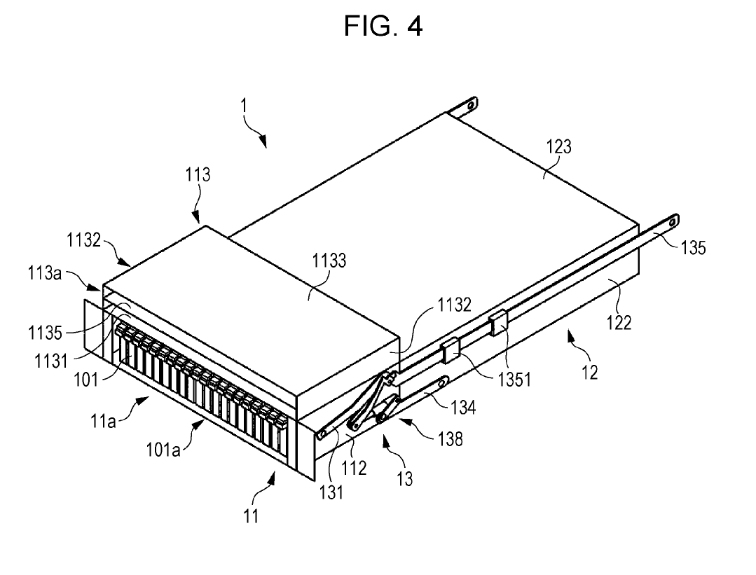

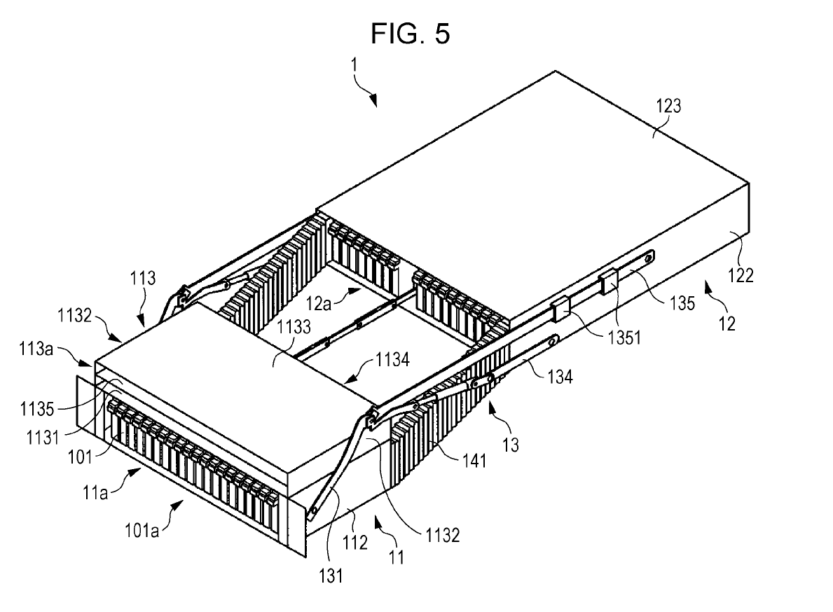

FIG. 1 is a perspective view illustrating an expanded state of a storage device as an example of the embodiment, and FIG. 2 is a perspective view illustrating a housed state of the storage device. In FIGS. 1 and 2, depiction of a base unit cover 123, ducts 141, 141, and an HDD shelf cover 113 that are illustrated in FIGS. 4, 5, and the like is omitted for description on inner configuration of the storage device 1.

The storage device (electronic equipment housing device) 1 is an electronic device that is to be mounted in a rack mount device not illustrated and is inserted into a slot formed in a rack of the rack mount device.

As illustrated in FIG. 1, the storage device 1 includes a base unit 12, an HDD shelf 11, and a connecting and disconnecting mechanism 13 and is configured so that the connecting and disconnecting mechanism 13 connects the base unit 12 and the HDD shelf 11.

The base unit (first housing part) 12 detachably includes one or more (sixteen in the example illustrated in FIG. 1) memory devices (first electronic devices) 101 on a rectangular base 121 and includes one or more (two in the embodiment) control units 16 and fans 14, 15.

The sixteen memory devices (first electronic equipment) 101 are placed along one side of the base 121 so as to be orthogonal to the side and so as to be parallel with one another. Hereinbelow, a side on which the memory devices 101 are arranged and placed on the base 121 will be referred to as front side as illustrated in FIG. 1, for convenience. The plurality of memory devices 101 arranged and placed on the base 121 of the base unit 12 will be referred to as a rear disk row 101b.

The memory devices 101 are hard disk drives (HDDs), solid state drives (SSDs), or the like, for instance. For the embodiment, the example in which the HDDs are used as the memory devices 101 is disclosed and the memory devices 101 will be represented as HDDs 101 hereinbelow.

The two control units 16 are arranged and placed in rear of the rear disk row 101b on the base 121. Controller modules (CMs), power supply units (PSUs), and the like are installed in the control units 16. The CMs control reading and writing of data on the HDDs 101, communication with host devices not illustrated, and the like. The PSUs supply power to parts in the storage device 1.

In the control units 16, the fans (first air flow producing part, second air flow producing part) 14 are placed along a rear side of the base 121.

Ventilation paths 201, 201 are placed along sides orthogonal to the front side described above on the base 121. The ventilation paths 201 are pipe-like members each having a rectangular section, for instance. The fan (third air flow producing part) 15 is provided in rear end part of each of the ventilation paths 201, 201.

Details of the fans 14, 15, and the ventilation paths 201, 201 will be described later.

A backplane 17 is stood between the rear disk row 101b and the control units 16 on the base 121 so as to be parallel with the front side described above and so as to be orthogonal to the base 121. The HDDs 101 on the base unit 12 are connected to connectors that are formed on the backplane 17 and that are not illustrated and are connected through the backplane 17 to the CMs and the PSUs in the control units 16.

In front of the base 121, a cable link guide 124 protrudes in parallel with the base 121. The backplane 17 and a backplane 18 that is provided in the HDD shelf 11 and that will be described later are connected through a communication cable and a power cable that are not illustrated. The communication cable and the power cable are guided by the cable link guide 124.

Side panels 122 are stood on the sides orthogonal to the front side described above on the base 121. The connecting and disconnecting mechanism 13 that will be described later is connected to the side panels 122.

The base unit cover 123 is placed on the base unit 12 so as to cover the rear disk row 101b and the control units 16 as illustrated in FIGS. 4 and 5, though depiction of the base unit cover 123 is omitted in the example illustrated in FIGS. 1 and 2 for convenience. In the base unit 12, in this manner, the rear disk row 101b, the control units 16, the fans 14, 15, and the ventilation paths 201, 201 are placed in a space surrounded by the base 121, the side panels 122, 122, and the base unit cover 123.

The HDD shelf (second housing part) 11 has one or more (twenty in the example illustrated in FIG. 1) HDDs (second electronic devices) 101 on a rectangular base 111.

The twenty HDDs 101 are placed along front side of the base 111 so as to be orthogonal to the side and so as to be parallel with one another. The plurality of HDDs 101 arranged and placed on the base 111 of the HDD shelf 11 will be referred to as a front disk row 101a.

The backplane 18 is stood in rear of the front disk row 101a on the base 111 so as to be parallel with the front side described above and so as to be orthogonal to the base 111. The HDDs 101 on the HDD shelf 11 are connected to connectors that are formed on the backplane 18 and that are not illustrated. The HDDs 101 on the HDD shelf 11 are connected through the backplane 18, cables not illustrated, and the backplane 17 to the CMs and the PSUs in the control units 16.

Side panels 112 are stood on sides orthogonal to the front side described above on the base 111.

The connecting and disconnecting mechanism 13 is connected to the side panels 112. The connecting and disconnecting mechanism 13 makes it possible to connect the base unit 12 and the HDD shelf 11, to switch at will a spaced state (see FIG. 1) in which the HDD shelf 11 and the base unit 12 are spaced apart and a close state (see FIG. 2) in which the HDD shelf 11 and the base unit 12 are made close to each other, and to maintain each state. Hereinbelow, the spaced state, illustrated in FIG. 1, in which the HDD shelf 11 and the base unit 12 are spaced apart will be referred to as expanded state of the HDD shelf 11 or simply as expanded state. In addition, the close state, illustrated in FIG. 2, in which the HDD shelf 11 and the base unit 12 are made close to each other will be referred to as housed state of the HDD shelf 11 or simply as housed state.

When the storage device 1 with the HDD shelf 11 being in the housed state is stored into a slot of a rack not illustrated, the HDD shelf 11 and the base unit 12 are housed in the slot of the rack. That is, depth of the storage device 1 is configured so that the storage device 1 fits within the rack. When the HDD shelf 11 is brought into the expanded state, the HDD shelf 11 is protruded from the slot of the rack and the rear disk row 101b in the base unit 12 are exposed.

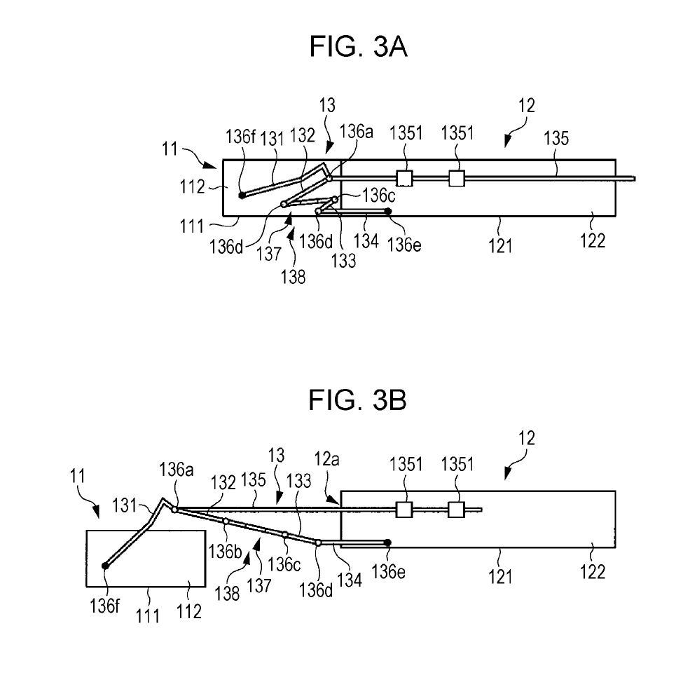

FIGS. 3A and 3B are side views illustrating operations of the connecting and disconnecting mechanism 13 in the storage device 1 as the example of the embodiment. FIG. 3A illustrates the housed state and FIG. 3B illustrates the expanded state.

In the housed state of the HDD shelf 11, as illustrated in FIG. 3A, the base 111 of the HDD shelf 11 is flush with the base 121 of the base unit 12.

As illustrated in FIGS. 3A and 3B, the connecting and disconnecting mechanism 13 includes a plurality of links 131 through 135 and dampers 137. As illustrated in FIG. 1 and the like, the plurality of links 131 through 135 and the dampers 137 are provided in positions that are on both side faces of the HDD shelf 11 and the base unit 12 and that are opposed with the HDD shelf 11 and the base unit 12 in between. In the connecting and disconnecting mechanism 13, namely, the links 131 through 135 and the dampers 137 that are provided on both the side faces of the HDD shelf 11 and the base unit 12 are paired and thereby perform respective functions.

The links 131 each have one end pivotally connected through a pivot 136f to the side panel 112 of the HDD shelf 11. Thus the links 131, 131 hold the HDD shelf 11 from both sides of the HDD shelf 11. The links 131 each have the other end pivotally connected through a pivot 136a to one end part of the link 135 and one end part of the link 132. That is, the links 131, 131 pivot on the pivots 136a while holding the HDD shelf 11 and thereby function as a vertical moving mechanism that vertically moves the HDD shelf 11. The links 131 have a shape bent like a letter L on a side near to the pivots 136a.

The links 135 have a linear shape and are slidably guided in front-rear directions by guides 1351, 1351 that are arranged in the front-rear direction on the side panels 122 of the base unit 12. The links 135 are restricted in vertical movement by the guides 1351, 1351 and support the links 131, 131 that hold the HDD shelf 11 in between as described above.

The links 135 that hold the HDD shelf 11 and the links 131, 131 in between move in the front-rear directions while being guided by the guides 1351, 1351, and the HDD shelf 11 is thereby spaced apart from or made close to the base unit 12. That is, the links 135 function as a horizontal moving mechanism that horizontally moves the HDD shelf 11 by being guided by the guides 1351, 1351 and that thereby changes distance from the base unit 12 to the HDD shelf 11.

The links 134 each have one end pivotally connected through a pivot 136e to the side panel 122 of the base unit 12 and each have the other end pivotally connected through a pivot 136d to one end part of the link 133.

The links 132, 133, and the dampers 137 form a link mechanism 138 that connects the end parts of the links 135 on a side including the pivots 136a and end parts of the links 134 on a side including the pivots 136d. The link mechanism 138 extensibly connects the end parts of the links 135 on the side including the pivots 136a and the end parts of the links 134 on the side including the pivots 136d. By supporting the HDD shelf 11, the link mechanism 138 distributes a load caused by the HDD shelf 11 and thus reduces concentration of the load on the links 135.

In the link mechanism 138, specifically, one end side of the link 133 is pivotally connected through the pivot 136d to the end part of the link 134 that is opposite to the pivot 136e. The end part of the link 133 that is opposite to the pivot 136d is pivotally connected through a pivot 136c to one end part of the damper 137. An end part of the damper 137 that is opposite to the end part thereof on the side including the pivot 136c is pivotally connected through the pivot 136b to one end side of the link 132.

The dampers 137 are a device that reduces impact or amplitude of vibrations by dissipating vibrational energy and reduce impact and vibrations that are produced by expansion and contraction of the link mechanism 138. The dampers 137, which reduce the impact and vibrations that are produced by the expansion and contraction of the link mechanism 138, make it possible to avoid transmission of the impact and vibrations to the HDDs 101 housed in the HDD shelf 11 and the base unit 12. That is, the HDDs 101 may be protected from the impact and vibrations that are produced by switching between the expanded state and the housed state of the HDD shelf 11 in active state of the storage device 1. The damper 137 are configured extensibly and contractibly.

The end part of the link 132 that is opposite to the end part thereof on the side including the pivot 136b is pivotally connected through the pivot 136a to the link 135 and the link 131.

In the housed state of the HDD shelf 11, as illustrated in FIG. 3A, the link mechanism 138 is brought into a folded state. In the link mechanism 138, specifically, the links 132, 133, and the dampers 137 are folded by pivoting on the pivots 136c and 136d. Then the dampers 137 contract. Thus the link mechanism 138 functions to decrease distance between the end part of the link 135 on the side including the pivot 136a and the end part of the link 134 on the side including the pivot 136d.

When the HDD shelf 11 is housed, as illustrated in FIG. 3A, the link mechanism 138 contracts and the links 135 move rearward by being guided by the guides 1351, 1351 in the connecting and disconnecting mechanism 13, while the HDD shelf 11 is held from both the sides.

Thus the HDD shelf 11 is placed in a position in which the base 111 is flush with the base 121 of the base unit 12, so that the housed state in which the HDD shelf 11 and the base unit 12 are close to each other is brought about. In the housed state, the HDD shelf 11 is laid on the cable link guide 124 and is thereby fixed in the state in which the HDD shelf 11 is close to the base unit 12.

In the expanded state of the HDD shelf 11, as illustrated in FIG. 3B, the links 132, 133, and the dampers 137 in the link mechanism 138 are expanded so as to be linear and support the HDD shelf 11. Then the dampers 137 are extended. Thus the link mechanism 138 functions to increase the distance between the end part of the link 135 on the side including the pivot 136a and the end part of the link 134 on the side including the pivot 136d.

When the HDD shelf 11 is in the expanded state, as illustrated in FIG. 3B, the link mechanism 138 is extended and the links 135 move forward by being guided by the guides 1351, 1351 in the connecting and disconnecting mechanism 13, while the HDD shelf 11 is held from both the sides.

Thus the HDD shelf 11 moves forward and away from the base unit 12, so that the HDD shelf 11 and the base unit 12 are brought into the spaced state. By contact with the links 131 of stoppers not illustrated and protruding from the side panels 112, for instance, pivoting of the HDD shelf 11 on the pivots 136f is blocked and the HDD shelf 11 is fixed so as to be horizontal in the expanded state.

In the expanded state of the HDD shelf 11, a space that allows work such as maintenance for the HDDs 101 or the like mounted on the base unit 12 is ensured in front of the base unit 12.

In the expanded state of the HDD shelf 11, as illustrated in FIGS. 1 and 3B, formation of an opening 12a on front face of the base unit 12 and exposure of the HDDs 101 mounted on the base unit 12 through the opening 12a make it possible to carry out work on the HDDs 101. In the expanded state of the HDD shelf 11, as will be described later, a state in which outside air (air) may flow through the opening 12a into the base unit 12 is brought about.

The storage device 1 as the example of the embodiment that is configured as described above is inserted in the housed state into the slot formed in the rack of the rack mount device.

An operator who performs maintenance work or the like draws out the HDD shelf 11 frontward in the storage device 1 inserted in the rack.

Then the links 132, 133, and the dampers 137 of the link mechanism 138 having been in the folded state are expanded so as to be linear. Consequently, the links 135 move forward while being guided by the guides 1351, 1351, and the HDD shelf 11 is thereby spaced apart from the base unit 12.

The operator then makes the HDD shelf 11, held between the links 131, 131, pivot (move) downward on the pivots 136a. Thus the HDD shelf 11 is positioned below the base unit 12 and the opening 12a is formed on the front face of the base unit 12 so that the rear disk row 101b is exposed.

Subsequently, a function of cooling the HDDs 101 in the storage device 1 will be described.

FIG. 4 is a perspective view illustrating an appearance of the housed state of the storage device as the example of the embodiment, and FIG. 5 is a perspective view illustrating an appearance of the expanded state of the storage device. In FIGS. 4 and 5, illustration of some reference characters is omitted, for convenience.

As illustrated in FIGS. 4 and 5, the base unit 12 includes the base unit cover 123 that covers the rear disk row 101b, the backplane 17, the control units 16, the ventilation paths 201, and the like so as to conceal them. That is, the disk row 101b, the backplane 17, the control units 16, and the ventilation paths 201 are placed in the space (base unit space) surrounded by the base 121, the side panels 122, 122, and the base unit cover 123.

Similarly, the HDD shelf 11 includes the HDD shelf cover 113 that covers the front disk row 101a and the backplane 18 so as to conceal them. That is, the front disk row 101a and the backplane 18 are placed in a space (HDD shelf space) surrounded by the base 111, the side panels 112, 112, a bottom surface 1131, and the HDD shelf cover 113.

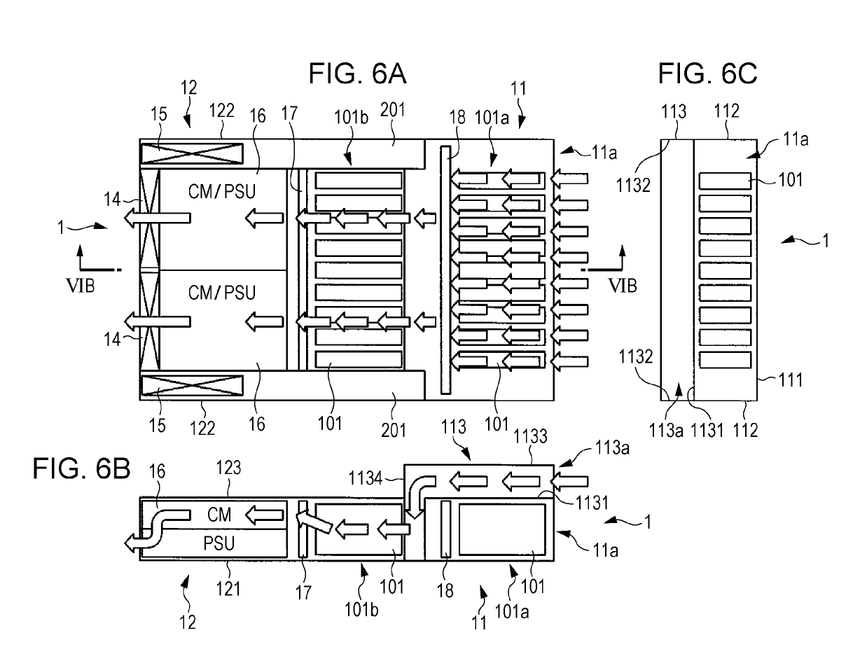

FIGS. 6A, 6B, and 6C illustrate paths of air flow that cools the rear disk row 101b in the housed state of the storage device 1 as the example of the embodiment. FIG. 6A is a plan view illustrating the paths of the air flow in the storage device 1. FIG. 6B is a section taken along line VIB-VIB of FIG. 6A. FIG. 6C is an elevational view of the storage device 1.

The HDD shelf cover 113 is shaped like a box surrounded by the bottom surface 1131, side plates 1132, 1132, a top plate 1133, and a rear plate 1134 and is placed so that the bottom surface 1131 is over the front disk row 101a in the HDD shelf 11 and parallels the base 121. The side plates 1132, 1132 are configured to be flush with the side panels 112, 112 of the HDD shelf 11.

An opening 113a is formed on front face of the HDD shelf cover 113 and a current plate 1135 (see FIG. 4) is provided in the opening 113a.

In the housed state, as illustrated in FIG. 6B, inner space of the HDD shelf cover 113 is connected to the base unit space in the base unit 12. When the fans 14 in the base unit 12 are rotated in the housed state, accordingly, air taken in through the opening 113a of the HDD shelf cover 113 flows from the inner space of the HDD shelf cover 113 into the base unit space, as illustrated in FIGS. 6A and 6B.

Specifically, the air taken in through the opening 113a of the HDD shelf cover 113 collides against the rear plate 1134, flows downward in the inner space of the HDD shelf cover 113, and flows into the base unit space.

The air having flowed into the base unit space passes through between the HDDs 101 of the rear disk row 101b and thereafter enters the control units 16. When passing through between the HDDs 101, the air cools the HDDs 101.

In the housed state of the HDD shelf 11, the inner space of the HDD shelf 11 thus functions as a guiding path that guides the air, taken in through the opening 113a, to the rear disk row 101b.

In the housed state, namely, the fans 14 produce the air flow that flows in through the guiding path and that passes through the HDDs 101 of the rear disk row 101b.

After that, the air having entered the control units 16 cools the CMs and the PSUs in the control units 16, passes through the fans 14, and is discharged from rear side of the base unit 12.

In the housed state of the HDD shelf 11, in this manner, the rear disk row 101b is cooled by the air flow that is taken in through the opening 113a of the HDD shelf cover 113 and that is guided by the inner space of the HDD shelf 11.

The HDD shelf space surrounded by the base 111, the side panels 112, 112, and the bottom surface 1131 of the HDD shelf cover 113 in the HDD shelf 11 communicates with the ducts 141, 141. On rear side (side facing the base unit 12) of the HDD shelf space, specifically, the ducts 141 couple the HDD shelf space to the ventilation paths 201 of the base unit 12.

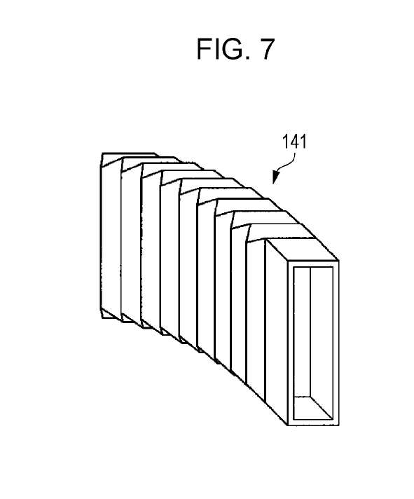

FIG. 7 is an outside drawing illustrating an example of the duct 141 in the storage device 1 as the example of the embodiment.

The duct 141 is a bellows hose having a rectangular section as illustrated in FIG. 7 and expands or contracts in accordance with the distance between the HDD shelf 11 and the base unit 12. The duct 141 is not limited to the bellows hose, may be configured with use of members that are made of rubber, for instance, and that expand or contract through agency of elasticity, and may be implemented with various modifications.

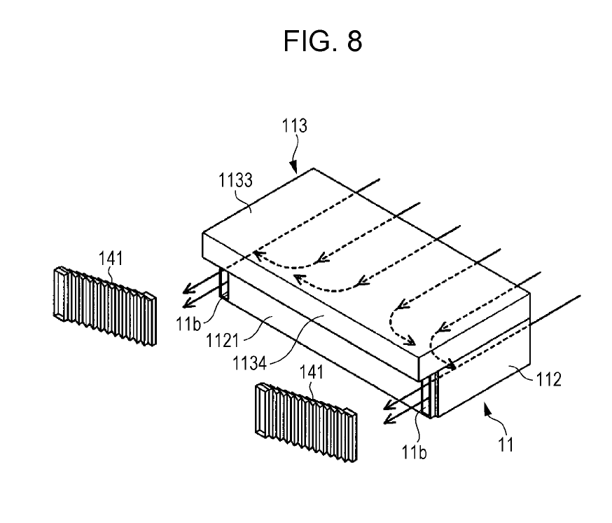

FIG. 8 is a perspective view illustrating an appearance of rear side of the HDD shelf 11 in the storage device 1 as the example of the embodiment. In FIG. 8, only a portion is extracted and depicted, for convenience.

As illustrated in FIG. 8, a rear plate 1121 is stood along rear side of the base 111 in rear part of the HDD shelf 11. In the rear part of the HDD shelf 11, rear openings 11b, 11b are formed between the rear plate 1121 and the side panels 112. Ends on one side of the ducts 141 described above are connected to the rear openings 11b, 11b. In FIG. 8, the ducts 141 and the rear openings 11b in a separated state are illustrated, for convenience, for depiction of positional relation between the ducts 141 and the rear openings 11b.

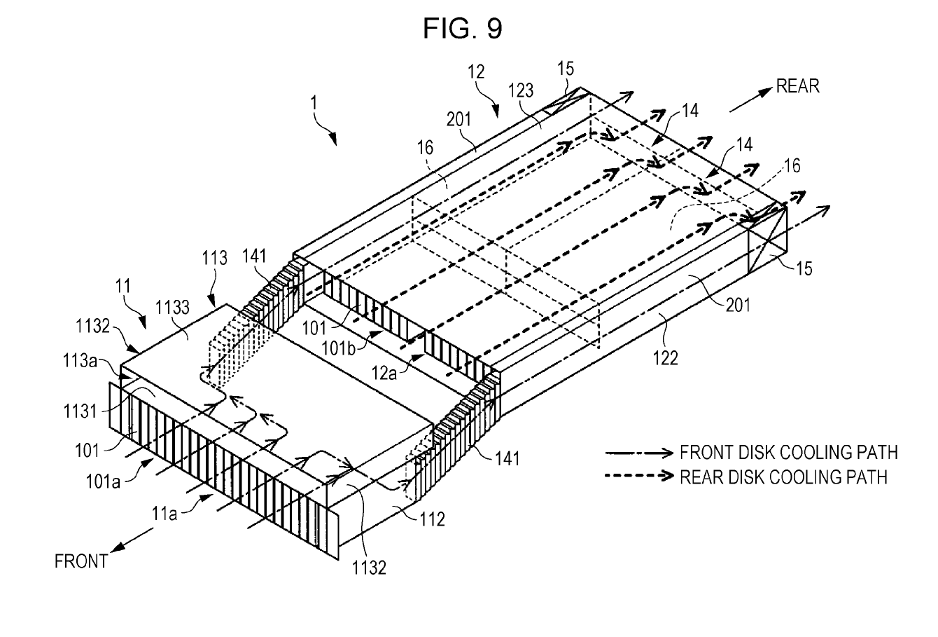

As illustrated in FIG. 9, air having entered through the front opening 11a on the HDD shelf 11 thus enters the ducts 141 through the rear openings 11b, 11b.

FIG. 9 is a perspective view illustrating paths of air flow in the expanded state of the storage device 1 as the example of the embodiment. In FIG. 9, the paths of the air flow that cools the front disk row 101a are represented by arrows of chain lines, and the paths of the air flow that cools the rear disk row 101b are represented by arrows of dashed thick lines. In FIG. 9, only a portion is extracted and depicted, for convenience.

In the expanded state of the HDD shelf 11 in such a configuration as described above, the rear disk row 101b is cooled by rotation of the fans 14, 14 in the base unit 12. With the rotation of the fans 14, 14, namely, the air sucked through the front opening 12a on the base unit 12 passes through between the HDDs 101 of the rear disk row 101b and thereafter enters the control units 16. When passing through between the HDDs 101, the air cools the HDDs 101.

After that, the air having entered the control units 16 cools the CMs and the PSUs in the control units 16, passes through the fans 14, and is discharged from the rear side of the base unit 12.

In the expanded state, namely, the fans 14 produce the air flow that flows in through the opening 12a of the base unit 12 and that passes through the HDDs 101 of the rear disk row 101b.

In the expanded state of the HDD shelf 11, the front disk row 101a is cooled by rotation of the fans 15, 15 in the base unit 12. With the rotation of the fans 15, 15, namely, the air sucked through the front opening 11a on the HDD shelf 11 passes through between the HDDs 101 of the front disk row 101a and thereafter enters the ducts 141, 141. When passing through between the HDDs 101, the air cools the HDDs 101.

In the expanded state of the HDD shelf 11, the front disk row 101a is thus cooled by the air sucked through the front opening 11a on the HDD shelf 11.

After that, the air having entered the ducts 141 passes through the ventilation paths 201, 201, thereafter passes through the fans 15, and is discharged from the rear side of the base unit 12.

In the expanded state, namely, the fans 15 produce the air flow that flows in through the opening 11a formed on the HDD shelf 11, that passes through the HDDs 101 of the front disk row 101a, and that thereafter passes through the ducts 141.

The air used for cooling the front disk row 101a passes through the rear openings 11b, 11b, the ducts 141 in an extended state, and the ventilation paths 201, 201, thereafter passes through the fans 15, and is discharged from the rear side of the base unit 12.

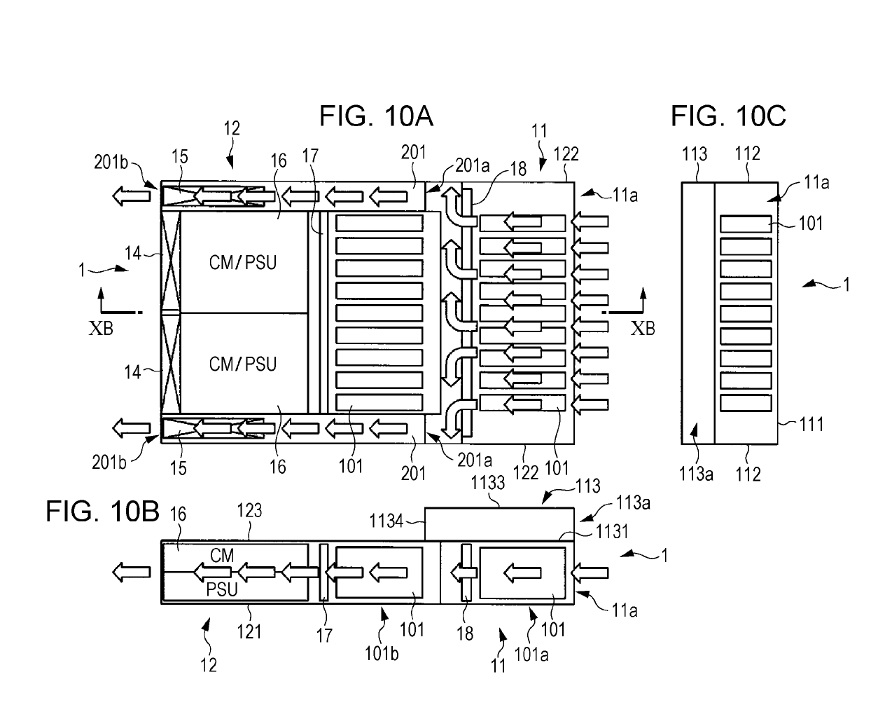

FIGS. 10A, 10B, and 10C illustrate the paths of the air flow that cools the front disk row 101a in the housed state of the storage device 1 as the example of the embodiment. FIG. 10A is a plan view illustrating the paths of the air flow in the storage device 1. FIG. 10B is a section taken along line XB-XB of FIG. 10A. FIG. 10C is an elevational view of the storage device 1.

The ducts 141 described above are contracted in the housed state and thus depiction of the ducts 141 is omitted in FIGS. 10A, 10B, and 10C.

The inner space (HDD shelf space) of the HDD shelf 11 is coupled through the ducts 141 to the ventilation paths 201 as described above. When the fans 15 in the ventilation paths 201 are rotated in the housed state, accordingly, the air taken in through the opening 11a of the HDD shelf 11 flows into the HDD shelf space, as illustrated in FIGS. 10A and 10B.

The air having flowed in passes through between the HDDs 101 of the front disk row 101a in the HDD shelf space. When passing through between the HDDs 101, the air cools the HDDs 101.

After passing through the front disk row 101a, the air passes through the rear openings 11b, 11b and the ducts 141 in a contracted state and flows into the ventilation paths 201, 201.

In the housed state also, namely, the fans 15 produce the air flow that flows in through the opening 11a formed on the HDD shelf 11, that passes through the HDDs 101 of the front disk row 101a, and that thereafter passes through the ducts 141.

Also in the housed state of the HDD shelf 11, the front disk row 101a is thus cooled by the air taken in through the opening 11a on the HDD shelf 11. The air used for the cooling passes through the rear openings 11b, 11b, the ducts 141 in the contracted state, and the ventilation paths 201, 201, thereafter passes through the fans 15, and is discharged from the rear side of the base unit 12.

According to the storage device 1 as the example of the embodiment, in this manner, the spaces in the storage device 1 may efficiently be used because the HDDs 101 may be housed in the base unit 12 and in the HDD shelf 11 so that a large number of HDDs 101 may be housed in the storage device 1.

Besides, the HDD shelf 11 is brought into the expanded state by the connecting and disconnecting mechanism 13, so that maintenance on the HDDs 101 of the rear disk row 101b may easily be performed. That is, improvement in maintainability and increase in convenience are attained.

The HDD shelf 11 may be spaced apart from the base unit 12 by being moved forward and horizontally by the links 135 guided by the guides 1351, 1351. Thus it is made possible to easily access the rear disk row 101b, and the space that allows performance of maintenance work on the HDDs 101 of the rear disk row 101b is ensured in front of the base unit 12.

The HDD shelf 11 may be positioned below the base unit 12 in the expanded state by the downward movement of the HDD shelf 11 around the pivots 136a in the state in which the HDD shelf 11 is held between the links 131, 131. Thus interference by the HDD shelf 11 with access to the rear disk row 101b is reduced, so that the access to the rear disk row 101b is further improved.

In addition, the front disk row 101a in the HDD shelf 11 and the rear disk row 101b in the base unit 12 may separately be cooled in the housed state of the HDD shelf 11. As a result, shortening of life of the HDDs 101 may be reduced and reliability may be increased.

That is, the rear disk row 101b may be cooled in the housed state of the HDD shelf 11 by the air that is taken in through the opening 113a of the HDD shelf cover 113 and that is guided by the inner space of the HDD shelf 11.

In the expanded state of the HDD shelf 11, the rear disk row 101b is cooled by the air sucked through the front opening 11a on the HDD shelf 11.

Thus the rear disk row 101b may be cooled in both the housed state and the expanded state of the HDD shelf 11.

The front disk row 101a is cooled by the air taken in through the opening 11a of the HDD shelf 11 in both the housed state and the expanded state of the HDD shelf 11. The air used for the cooling passes through the rear openings 11b, 11b, the ducts 141, and the ventilation paths 201, 201, thereafter passes through the fans 15, and is discharged from the rear side of the base unit 12.

The ducts 141 are in the contracted state when the HDD shelf 11 is in the housed state or are in the extended state when the HDD shelf 11 is in the expanded state. Thus the air taken in through the opening 11a of the HDD shelf 11 may be discharged through the fans 15 in both the housed state and the expanded state of the HDD shelf 11.

Thus the front disk row 101a may be cooled in both the housed state and the expanded state of the HDD shelf 11.

Techniques disclosed herein are not limited to the embodiment described above and may be implemented with various modifications without departing from purport of the embodiment.

In the embodiment described above, for instance, the connecting and disconnecting mechanism 13 includes the five pairs of links 131 through 135 and the dampers 137 and is folded by the pivoting of the links 132, 133, and the dampers 137 on the pivots 136c and 136d in the housed state of the HDD shelf 11. Configuration of the connecting and disconnecting mechanism 13, however, is not limited to above. The connecting and disconnecting mechanism 13 may include four or less pairs or six or more pairs of links and may be implemented with various modifications.

Though the connecting and disconnecting mechanism 13 includes the dampers 137 in the embodiment described above, the connecting and disconnecting mechanism 13 is not limited to the embodiment and may include simple links 137′ in place of the dampers 137.

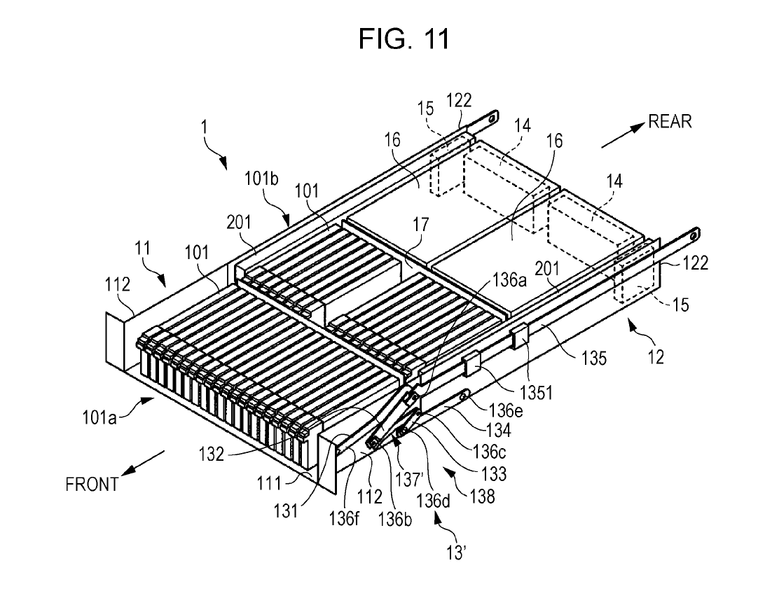

FIG. 11 is a perspective view illustrating a housed state of the storage device as a modification of the embodiment.

The storage device 1 illustrated in FIG. 11 includes a connecting and disconnecting mechanism 13′ in place of the connecting and disconnecting mechanism 13 of the storage device 1 illustrated in FIG. 2. The connecting and disconnecting mechanism 13′ includes the simple links 137′ in place of the dampers 137. Thus production costs for the connecting and disconnecting mechanism 13′ may be reduced.

Numbers of the HDDs 101 housed in the base unit 12 and the HDD shelf 11 are not limited to numbers disclosed in the embodiment described above and may be set with various modifications.

Though the storage device 1 that houses the memory devices 101 as electronic devices has been described for the embodiment described above, the electronic devices are not limited to above and may be implemented with various modifications. For instance, electronic devices such as information processing devices and communication devices, other than memory devices, may be housed as the electronic devices. Electronic devices stored in the base unit 12 and electronic devices stored in the HDD shelf 11 may be different.

According to disclosure described above, the embodiment may be implemented and produced by a person skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic equipment housing device comprising:
a first housing part in which first electronic equipment is housed;
a second housing part in which second electronic equipment is housed; and
a connecting and disconnecting mechanism that switches a spaced state in which the second housing part is spaced apart from the first housing part and a close state in which the second housing part is made close to the first housing part.

2. The electronic equipment housing device according to claim 1,
wherein the connecting and disconnecting mechanism includes
a horizontal moving mechanism that horizontally moves the second housing part and that thereby changes distance from the first housing part to the second housing part, and
a vertical moving mechanism that vertically moves the second housing part and that thereby changes the distance from the first housing part to the second housing part.

3. The electronic equipment housing device according to claim 1, further comprising:
a first air flow producing part that produces air flow which flows in through an opening formed on the first housing part and which passes through the first electronic equipment, in the spaced state in which the second housing part is spaced apart from the first housing part.

4. The electronic equipment housing device according to claim 1,
wherein the second housing part includes a guiding path that guides air flow from outside of the electronic equipment housing device to the first electronic equipment in the first housing part in the close state in which the second housing part is made close to the first housing part, and
the electronic equipment housing device further includes a second air flow producing part that produces the air flow which flows in through the guiding path and which passes through the first electronic equipment, in the close state.

5. The electronic equipment housing device according to claim 1, further comprising:
ducts that extensibly connect the first housing part and the second housing part; and
a third air flow producing part that produces air flow which flows in through an opening formed on the second housing part, which passes through the second electronic equipment, and which thereafter passes through the ducts.
